(19) United States
(12) Patent Application Publication
(10) Pub. No.: US 2007/0126021 A1
(43) Pub. Date: Jun. 7, 2007

(54) Metal oxide semiconductor film structures and methods

(76) Inventors: Yungryel Ryu, Columbia, MO (US); Tae-seok Lee, Naperville, IL (US); Henry W. White, Columbia, MO (US)

Correspondence Address: JACOBS & KIM LLP, 1050 WINTER STREET, SUITE 1000, #1082, WALTHAM, MA, 02451-1401, US

(21) Appl. No.: 11/295,686

(22) Filed: Dec. 6, 2005

(51) Int. Cl. H01L 33/00

(52) U.S. Cl. 257/103

(57) ABSTRACT

Layered and film structures for improving the performance of semiconductor devices include single and multiple quantum wells and double heterostructures and superlattice structures.

### FIELD OF THE INVENTION

The present invention relates generally to semiconductors, and, more particularly, to zinc oxide based and other metal oxide and metal oxide alloy based semiconductor devices and film structures.

### BACKGROUND OF THE INVENTION

The optical properties of zinc oxide (ZnO) have been studied for potential use in semiconductor devices, in particular for photonic light emitting devices such as light emitting diodes (LEDs) and laser diodes (LDs) and photonic detectors such as photodiodes. The energy band gap of ZnO is approximately 3.3 electron volt (eV) at room temperature, corresponding to a wavelength of approximately 376 nanometer (nm) for an emitted photon of this energy. Light emission has been demonstrated from ZnO LEDs using p-type and n-type materials to form a diode. ZnO has also been used to fabricate a UV photodetector and a field effect transistor (FET).

ZnO has several important properties that make it a promising semiconductor material for optoelectronic devices and applications. ZnO has a large exciton binding energy, 60 meV, compared with 26 meV for GaN and 20 meV for ZnSe. The large exciton binding energy for ZnO indicates promise for fabrication of ZnO-based devices that would possess bright coherent emission/detection capabilities at elevated temperatures. ZnO has a very high breakdown electric field, estimated to be about 2×10⁶ V/cm (>two times the GaAs breakdown field), indicating thereby that high operation voltages could be applied to ZnO-based devices for high power and gain. ZnO also has a saturation velocity of 3.2×10⁷ cm/sec at room temperature, which is larger than the values for gallium nitride (GaN), silicon carbide (SiC), or gallium arsenide (GaAs). Such a large saturation velocity indicates that ZnO-based devices would be better for high frequency applications than ones made with these other materials.

Still further, ZnO is exceptionally resistant to radiation damage by high energy radiation. Common phenomena in semiconductors caused by high-energy radiation are the creation of deep centers within the forbidden band as well as radiation-generated carriers. These effects significantly affect device sensitivity, response time, and read-out noise. Therefore, radiation hardness is very important as a device parameter for operation in harsh environments such as in space and within nuclear reactors.

From the perspective of material radiation hardness, ZnO is much better suited for space operation than other wide bandgap semiconductors. For example, ZnO is about 100 times more resistant than is GaN against damage by high-energy radiation from electrons or protons.

ZnO also has a high melting temperature, near 2000° C., providing possibilities for high temperature treatments in post-growth processes such as annealing and baking during device fabrication, as well as for applications in high temperature environments.

Large-area ZnO single crystal wafers (up to 75 mm diameter) are commercially available. It is possible to grow homo-epitaxial ZnO-based devices that have low dislocation densities. Homo-epitaxial ZnO growth on ZnO substrates will alleviate many problems associated with hetero-epitaxial GaN growth on sapphire, such as stress and thermal expansion problems due to the lattice mismatch.

ZnO has a shallow acceptor level, 129 meV, compared with 215 meV for GaN. The low value for the acceptor level means that p-type dopants in ZnO are more easily activated and thereby help generate a higher hole concentration in ZnO than the corresponding hole concentration in GaN for the same dopant level concentration in each material. These properties make ZnO a most attractive material for development of near- to far-UV detectors, LEDs, LDs, FETs, and other optoelectronic devices.

It would be desirable to modify the energy band gap of ZnO to smaller values than that for ZnO and also to larger values than that for ZnO in order to provide for increased function, capability and performance of semiconductor devices.

By way of example, it is well known that the wavelength emitted by an LED or LD can be made smaller by increasing the value of the energy band gap of the semiconductor active layer in which light emission occurs. The energy band gap of ZnO can be increased by alloying ZnO with a suitable material using a suitable growth method. Conversely, the wavelength emitted by an LED or LD can be made larger by decreasing the value of the energy band gap of the semiconductor active layer in which light emission occurs. The energy band gap of ZnO can be decreased by alloying ZnO with a suitable material using a suitable growth method.

The terms “band gap modulation” and “band gap engineering” are used herein to refer to changing the band gap of a material to either increase or decrease the value of the energy band gap. Band gap modulation can be used to increase photon and carrier confinement in a semiconductor device. It can also be used to tailor the wavelength of light emission in a light emitting semiconductor device and to improve the response characteristics of a photodetector semiconductor device.

The prior art shows research that involved increasing the energy band gap of ZnO to 3.99 eV at room temperature by alloying ZnO with magnesium (Mg) to form ZnMgO; namely, Zn_{1-w} Mg_{w}O. As the content of Mg was increased up to w=0.33, the energy band gap was increased to 3.99 eV. Heterostructures were fabricated by using ZnO and ZnMgO layers.

However, a crystal phase separation occurs between MgO and ZnO if the Mg-content exceeds the value corresponding to w=0.33, due to the different crystal structure between ZnO and MgO and large difference in lattice constants. MgO has a cubic lattice structure with lattice spacing 0.422 nm, whereas ZnO is hexagonal with 0.325 nm. Therefore, ZnMgO alloys are limited in use for increasing the energy band gap in semiconductor devices up to 3.3 eV but not to larger energy band gap values.

For simplicity of growth, it would be desirable to have an alloy system comprised of one set of elements to cover the energy band gap range from approximately 3.3 eV to an energy band gap value of approximately 10.6 eV, corresponding to a wavelength of approximately 117 nm.

Conversely, beryllium oxide (BeO) has an energy band gap of approximately 10.6 eV at room temperature, corresponding to a wavelength of approximately 117 nm (O. Madelung). BeO has a hexagonal lattice structure.

For simplicity of growth, it would be desirable to have an alloy system comprised of one set of elements to cover the energy band gap range from approximately 3.3 eV to an energy band gap value of approximately 1.75 eV, corresponding to a wavelength of 710 nm.

Cadmium selenide (CdSe) has an energy band gap of approximately 1.75 eV, corresponding to a wavelength of approximately 710 nm. CdSe can be grown with a hexagonal lattice structure using proper growth conditions. Zinc selenide (ZnSe) has an energy band gap of approximately 2.8 eV, corresponding to a wavelength of approximately 444 nm. ZnSe can be grown with a hexagonal lattice structure using proper growth conditions. ZnO, BeO, CdSe, CdO and ZnSe are Group II-VI compounds.

Collectively, the energy band gap values for ZnO based alloys comprised of the two alloy systems—ZnBeO, namely, Zn₁₋ₓBeₓO, with x varying between 0 and 1 as required, and ZnCdOSe, namely, Zn_{1-y}Cd_{y}O_{1-z}Se_{z}, with y varying between 0 and 1 as required and with z varying between 0 and 1 independently as required—would span the range from approximately 10.6 eV to approximately 1.75 eV, corresponding to a wavelength range from approximately 117 nm to approximately 710 nm.

Semiconductor layers and structures comprised of ZnO, ZnO based alloys, BeO, BeO based alloys, metal oxides and metal oxide alloys of n-type or p-type conductivity can be prepared by introducing suitable dopant materials using a suitable growth method. Such methods are disclosed and claimed in commonly owned patent applications U.S. 60/406,500, PCT/US03/27143 and U.S. Ser. No. 10/525,611, filed Aug. 28, 2002, Aug. 27, 2003 and Feb. 23, 2005, respectively discussed in greater detail below incorporated herein by reference as if set forth herein in their entireties.

Semiconductor structures and devices fabricated from ZnO, ZnO alloys, BeO, BeO alloys, ZnCdSeO, ZnCdSeO alloys, and other metal oxide, and metal oxide alloy based materials that can operate with increased performance, capability and function are desirable for use in many commercial and military sectors including, but not limited to devices and areas such as light emitters, photodetectors, FETs, PN diodes, MSN structures, PIN diodes, NPN transistors, PNP transistors, transparent transistors, circuit elements, communication networks, radar, sensors and medical imaging.

It would therefore be desirable to provide zinc oxide based and other metal oxide and metal oxide alloy based semiconductor devices and film structures, and in particular, semiconductor devices with desirable structures comprised of layers and layered structures having selected energy band gap values and possibly containing dopants and one or more other elements. Such semiconductor layers and structures could be used to fabricate high performance semiconductor devices and structures and to improve the function and performance of semiconductor devices. They could also be used, for example, to detect or emit at one or a multiplicity of wavelengths in the UV and visible and THz spectral regions.

It would also be desirable to provide semiconductor devices with layered structures that can be tailored to have desired properties, and which are composed of layers with energy band gap values that can be selected, for example, by adjusting the atomic fractions of elements in a ZnO based semiconductor alloy material; or the atomic fraction of Be in a ZnBeO based semiconductor alloy material; or the atomic fraction of Cd and the atomic fraction of Se in a ZnCdOSe semiconductor alloy material, all of which could be used to improve the function, capability and performance of a semiconductor device.

### SUMMARY OF THE INVENTION

The invention addresses the above-described needs by providing semiconductor devices and semiconductor layer structures for improving the performance of semiconductor devices, including but not limited to devices with layer structures comprised of metal oxide materials, ZnO materials, BeO materials, ZnBeO alloy materials, ZnCdOSe alloy materials, and ZnO and ZnBeO alloy materials that may contain Mg for lattice matching purposes, and ZnCdOSe alloy materials that may contain Be for lattice matching purposes.

The atomic fraction x of Be in the ZnBeO alloy system, namely, Zn₁₋ₓBeₓO, can be varied to increase the energy band gap of ZnO to values larger than that of ZnO.

The atomic fraction y of Cd and the atomic fraction z of Se in the ZnCdOSe alloy system, namely, Zn_{1-y}Cd_{y}O_{1-z}Se_{z}, can be varied to decrease the energy band gap of ZnO to values smaller than that of ZnO.

Each alloy formed can be undoped, or p-type or n-type doped, by use of one or more selected dopant elements.

These alloys can be used alone or in combination to form semiconductor active photonic layers and semiconductor devices that can emit and detect at one or a multiplicity of wavelengths over a wide range of wavelength values and can be used to form semiconductor heterostructures, semiconductor active layers, quantum wells, multiple quantum wells, superlattice layers, reflection layers, absorption layers, transmission layers, isolation layers, light reflecting films and multilayers, metal contact layers, passivation layers, confinement layers, cladding layers, optical waveguide layers, cap layers, and substrates.

Other embodiments, examples, features and aspects of the present invention will also be disclosed herein. The foregoing description and other objects, advantages, and features of the invention and the manner in which the invention is accomplished will become more apparent after considerations of the following detailed description of the invention taken in conjunction with the accompanying drawings.

### BRIEF DESCRIPTION OF THE DRAWINGS

FIG. 1 is a schematic of a ZnO based semiconductor LED device in accordance with the invention that has a multiple quantum well (MQW) structure.

FIG. 2 is a schematic of a ZnO based semiconductor p-n junction structure device in accordance with the invention.

FIG. 3 is a schematic of a ZnO based semiconductor p-n junction device in accordance with the invention, with a DH structure.

FIG. 4 is a schematic showing room temperature I-V characteristics for a MQW ZnO based semiconductor LED device with structure as shown in FIG. 1.

FIG. 5 is a schematic showing room temperature I-V characteristics for a double heterostructure (DH) ZnO based semiconductor p-n junction with structure as shown in FIG. 3.

FIG. 6 is a schematic showing room temperature I-V characteristics for a homostructure ZnO based semiconductor p-n junction formed on an n-type SiC substrate.

### DETAILED DESCRIPTION OF THE INVENTION

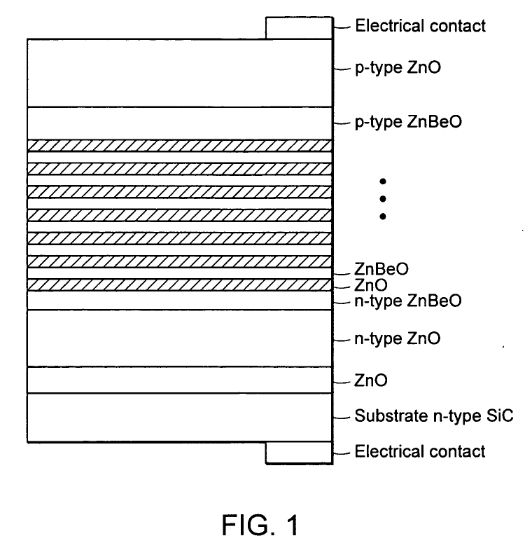

The present invention, aspects and examples of which are illustrated in the attached FIGS. 1-6, provides semiconductor devices and semiconductor layer structures for improving the performance of semiconductor devices, including but not limited to devices with layer structures comprised of metal oxide materials, ZnO materials, BeO materials, ZnBeO alloy materials, ZnCdOSe alloy materials, and ZnO and ZnBeO alloy materials that may contain Mg for lattice matching purposes, and ZnCdOSe alloy materials that may contain Be for lattice matching purposes. Before entering into a discussion of these examples, embodiments and aspects, the Applicants note that the following detailed description refers to various types of structures that can be fabricated in accordance with the invention, including the following:

Types of Structures

Multiple Layers of Different Energy Band Gaps: It is conceivable that a semiconductor device constructed in accordance with the present invention can advantageously utilize one layer to have an energy band gap smaller than that for ZnO, while another layer in the device may require an energy band gap that is larger than that for ZnO. For example, ZnO can be employed as a material in a UV detector. For applications of near-to-far UV detection, the fabrication of p-type/n-type (PN) layered structures, the fabrication of heterojunction p-type/intrinsic/n-type (PIN) layered structures and metal-semiconductor-metal (MSM) photodiodes, the energy band gap of ZnO should be modulated from 3.3 eV upward to larger energy band gap values. It is also conceivable that a semiconductor device may require a layer to contain either a dopant for producing a p-type semiconductor layer, or a dopant for producing an n-type layer, or to contain no dopant. These aspects will be discussed in greater detail below.

Active Layer Region: The semiconductor active layer or semiconductor active layer region of a semiconductor light emitting device, such as an LED or an LD, pertains to the semiconductor layer from which light is emitted. Electrical carriers of n-type or p-type conductivity combine in the active layer. The active layer or region may be a layer of single composition, or may be comprised of layers with more than one composition that are formed by successive lamination of layers.

SL: A semiconductor superlattice (SL) structure is comprised of laminated layers having different material composition that may have different energy band levels or may have the same energy band level. It is possible to have all layers in a SL to be doped, either n-type or p-type, either intrinsic or by addition of impurity elements to the layers. A SL may be also undoped. A SL may have a more complex doping pattern, such as, for example, doping of alternate layers to be n-type and wherein the intervening layers are undoped.

SQW: A single quantum well (SQW) structure is one type of superlattice structure. A SQW is comprised of a quantum well layer with thickness on the order of a de Broglie wavelength that is bounded by one or a multiplicity of barrier layers on each side of the quantum well layer with the energy gap values of barrier layers larger than the energy gap value of the quantum well layer, thereby forming a quantum well wherein the thicknesses of layers in the quantum well structure are such that one or more discrete quantum energy levels are formed in the quantum well. Typically, the thickness of the quantum well layer is less than about 10 nm and greater than about 0.5 nm, and typically the total thicknesses of the bounding layers are in the range from about 10 nm to 500 nm. The layers in an SQW may be doped or undoped. The values of the discrete quantum well energy levels may influence the emitted spectral output. This property is useful since the emitted spectral output may be altered in a desired manner by proper selection of the composition, energy band gap values, and thicknesses of individual layers that form the quantum well structure.

MQWs: A multiple quantum well (MQW) structure is another type of superlattice structure. An MQW structure is comprised of a set of more than one quantum well layers and intervening barrier structures comprised of one or a multiplicity of layers with the energy band gap of the barrier structures larger than the energy band gap values of associated quantum well layers such that a multiplicity of quantum wells are formed with each well containing one or more discrete energy levels. The thicknesses of the individual quantum well layers and of the individual barrier layers and structures in an MQW structure are selected to have values in the ranges typical for a SQW structure. The layers in an MQW may be doped or undoped.

Semiconductor Homostructure: A semiconductor homostructure is comprised of two semiconductor materials with each material having the same composition and the same energy band gap. The two materials may be undoped, or both doped the same as either n-type or p-type, or one doped as n-type and the other as p-type.

Semiconductor Heterostructure: A semiconductor heterostructure is comprised of two semiconductor materials that have different composition and that, in general, have different energy band gap values. The two materials may be undoped, or both doped the same as either n-type or p-type, or one doped as n-type and the other as p-type.

DH: A semiconductor double heterostructure (DH) is comprised of three layers laminated successively to form two interfaces for which there is a difference in energy band gap or material composition on each side of an interface. A semiconductor device with a double heterostructure is comprised of an interior layer with an energy gap smaller than each of the bounding layers, or of a multiplicity of layers in a bounding layer structure, that are located on each side of the interior layer. The materials forming the layers and structures in a double heterostructure may be undoped, or n-type or p-type doped, or a combination thereof. A light emitting device with a DH structure is comprised of an interior layer that serves as the active layer having an energy gap value that is lower than the energy gap value for each of the bounding layers or bounding layer structures, and wherein the active layer is the layer where electron and hole recombination and light emission occur. The thickness of the semiconductor active layer in such a DH structure is selected to be sufficiently high that characterization of the structure does not show the presence of one or more quantized energy levels in the DH well structure. The thickness of the active layer in such a device is typically in the range from about 10 nm to about 100 nm, and may be larger.

Strained SL: A strained SL semiconductor structure is comprised of laminated layers of semiconductor material having different composition and wherein each layer is sufficiently thin that each layer can strain if necessary to form an epitaxial layer with adjacent layers. The layers may have different concentrations of n-type dopant elements or may have different concentrations of p-type dopant elements, or may be undoped. A strained SL layered structure in lieu of a thick layer of uniform composition can be used to fabricate more efficient devices by reducing strain that may be created by use of a thick layer of a semiconductor material of uniform composition.

Confinement Layer: A semiconductor confinement layer or confinement layer structure is comprised of one or more semiconductor layers with energy band gap and composition selected for the purpose of containing light to a desired region within a semiconductor device to increase device lifetime and performance. A confinement structure may be comprised of a single layer, a multiplicity of layers, or an SL structure or other structure having a multiplicity of layers.

Cladding Layer: A semiconductor cladding layer or a semiconductor cladding structure is comprised of one or more semiconductor layers with energy band gap and composition selected for containing electrical charge carriers, either electrons, holes, or electrons and holes, to a desired region within a semiconductor device to increase device lifetime and performance. A cladding structure may be comprised of a single layer, a multiplicity of layers, or an SL structure or other structure having a multiplicity of layers.

Optical Waveguide Layer: A semiconductor optical waveguide layer has a low refractive index and functions as a light waveguide layer for an active layer. A cap layer that has a refractive index higher than the optical waveguide layer may function to contain light in a region, such as an optical waveguide layer. A cap layer may also be used as a layer on which an electrical contact is formed. A cap layer may also serve as a protective layer.

Passivation Layer: A semiconductor passivation layer or a semiconductor passivation structure is comprised of one or more semiconductor layers with energy band gap and composition selected for the purpose of providing protection to layers and structures within a semiconductor device and to the semiconductor device, and of decreasing current leakage in the device in order to increase device lifetime and performance. A passivation structure may be comprised of a single layer, a multiplicity of layers, or an SL structure or other structure having a multiplicity of layers.

Epitaxially Layered Structures: Various designs for epitaxially layered structures have been disclosed to increase performance of semiconductor devices. Among these designs are semiconductor structures that are comprised of layers of materials that have different composition and energy band gaps. Such structures include but are not limited to quantum wells, multiple quantum wells, superlattice layers, reflection layers, absorption layers, transmission layers, isolation layers, light reflecting films and multilayers, metal contact layers, passivation layers, confinement layers, cladding layers, optical waveguide layers, cap layers, and substrates.

The following discussion of examples, embodiments and practices of the present invention will also be illuminated by a brief discussion of the Applicants' hybrid beam deposition (HBD) process.

The Applicants' HBD Process

The energy band gap modulated materials described herein should have high crystalline quality so that semiconductor devices fabricated from these materials have high performance characteristics. ZnO and ZnO alloy materials that are used to fabricate semiconductor devices with high function, capability and performance require a growth process with function and capability for proper control of film growth, composition, and quality and capability for growing undoped material, p-type doped semiconductor material, and n-type semiconductor material and for growth of layers and heterostructures using these layers.

In this regard, the Applicants have succeeded in growing p-type ZnO using an external As-molecular beam to incorporate As-dopant into the film rather than by As-diffusion. The Applicants have termed this process a Hybrid Beam Deposition (HBD) process (as the term HBD is used throughout this document to refer to the Applicants' process), which is described in commonly-owned Patent Applications U.S. 60/406,500, PCT/US03/27143 and U.S. Ser. No. 10/525,611, filed Aug. 28, 2002, Aug. 27, 2003 and Feb. 23, 2005, respectively, each of which is hereby incorporated by reference as if set forth herein in its entirety.

The Applicants' HBD process for producing As-doped p-type ZnO films can be used to precisely control the doping level. The optical and electrical properties of ZnO:As grown by HBD are discussed in the above-cited, commonly owned patent applications incorporated herein by reference. In particular, hole carrier concentrations sufficiently high for semiconductor layers and structures and for device fabrication can be obtained. The thermal binding energy of the As-acceptor (E_{A}^{th-b}) is 129 meV, as derived from temperature-dependent Hall Effect measurements. The PL spectra reveal two different acceptor levels (E_{A}^{opt-b}), located at 115 and 164 meV, respectively, above the maximum of the ZnO valence band, and also show the binding energy of the exciton to the As-acceptor (E_{AX}^{b}) is about 12 meV. The quality of p-type ZnO:As layers grown by HBD are sufficiently high for device fabrication.

The Applicants also note that wide band gap semiconductor materials have utility for device operation at high temperatures. Zinc oxide is a wide band gap material, and it also possesses good radiation resistance properties. Wide band gap semiconductor films of zinc oxide are now available in both n-type and p-type carrier types that have properties sufficient for fabrication of semiconductor devices.

By way of example, U.S. Pat. No. 6,291,085 (White et al.) discloses a p-type doped zinc oxide film, and wherein the film could be incorporated into a semiconductor device including an FET.

U.S. Pat. No. 6,342,313 (White et al.) discloses a p-type doped metal oxide film having a net acceptor concentration of at least about 10¹⁵ acceptors/cm³, wherein the film is an oxide compound of an element selected from the groups consisting of Group 2 (beryllium, magnesium, calcium, strontium, barium and radium), Group 12 (zinc, cadmium and mercury), Group 2 and 12, and Group 12 and Group 16 (oxygen, sulfinur, selenium, tellurium and polonium) elements, wherein the p-type dopant is an element selected from the groups consisting of Group I (hydrogen, lithium, sodium, potassium, rubidium, cesium and francium), Group 11 (copper, silver and gold), Group 5 (vanadium, niobium and tantalum) and Group 15 (nitrogen, phosphorous, arsenic, antimony and bismuth) elements.

U.S. Pat. No. 6,410,162 (White et al.) discloses a p-type doped zinc oxide film wherein the p-type dopant is selected from Group 1, 11, 5 and 15 elements, and wherein the film can be incorporated into a semiconductor device including an FET, or into a semiconductor device as a substrate material for lattice matching to materials in the device.

The above-referenced patents and disclosures, including the above-referenced U.S. Pat. Nos. 6,291,085; 6,342,313 and 6,410,162, are incorporated by reference herein.

The Applicants' HBD process, as noted above and described in the cited, commonly owned patent documents incorporated herein by reference, enables the production of high quality semiconductor material including, but not limited to, undoped ZnO, p-type doped ZnO, n-type doped ZnO, undoped BeO, p-type doped BeO, n-type doped BeO, undoped ZnBeO alloys, p-type doped ZnBeO alloys, n-type doped ZnBeO alloys, undoped ZnCdOSe alloys, p-type doped ZnCdOSe alloys, n-type doped ZnCdOSe alloys.

(In this document, the term ZnBeO alloy is used to refer to Zn₁₋ₓBeₓO alloy, wherein the atomic fraction x of Be varies from 0 to 1, or as it may be specified. In an alternate notation, the term ZnBeO alloy is used herein to refer to Zn₁₋ₓBeₓO alloy, wherein 0≦x≦1, or as it may be specified. Similarly, the term ZnCdOSe alloy is used to refer to Zn_{1-y}Cd_{y}O_{1-z}Se_{z} alloy, wherein the atomic fraction y of Cd varies from 0 to 1 and the atomic fraction z of Se varies from 0 to 1, independently, as values for y and z may each be specified. In an alternate notation, the term ZnCdOSe alloy is used herein to refer to Zn_{1-y}Cd_{y}O_{1-z}Se_{z} alloy, wherein 0≦y≦1 and 0≦z≦1, independently, as values for y and z may each be specified.)

The Applicants also note the following additional aspects, with relevance to the present invention as described in detail below:

ZnO and BeO are Group II-VI compounds with energy band gap values of 3.3 eV and 10.6 eV, respectively. ZnO has a hexagonal crystal structure when grown under proper conditions. BeO has a hexagonal crystal structure when grown under proper conditions. From a consideration of Vernard's Law, ZnO and BeO can be mixed in a proper ratio to attain a particular energy band gap value between approximately 3.3 eV and approximately 10.6 eV. More specifically, according to Vernard's Law, the energy band gap for the alloy Zn_{0.9}Be_{0.1}O should be greater than the approximately 3.3 eV for ZnO by the amount of approximately 0.73 eV.

ZnO and CdSe are Group II-VI compounds with energy band gap values of approximately 3.3 eV and approximately 1.75 eV, respectively. CdSe has a hexagonal crystal structure when grown under proper conditions. From a consideration of Vernard's Law, ZnO and CdSe can be mixed in a proper ratio to attain a particular energy band gap value between approximately 3.3 eV and approximately 1.75 eV.

ZnO and ZnSe are Group II-VI compounds with energy band gap values of approximately 3.3 eV and approximately 2.8 eV, respectively. ZnSe has a hexagonal crystal structure when grown under proper conditions. From a consideration of Vernard's Law, ZnO and ZnSe can be mixed in a proper ratio to attain a particular energy band gap value between approximately 3.3 eV and approximately 2.8 eV.

An epitaxially layered material with an energy band gap between approximately 10.6 and approximately 3.3 eV can be designed, wherein the material can be undoped, p-type doped, or n-type doped.

An epitaxially layered material with an energy band gap between approximately 1.75 eV and approximately 3.3 eV can be designed, wherein the material can be undoped, p-type doped, or n-type doped.

The power, efficiency, function and speed of a semiconductor device is limited by the mobility of carriers, either n-type or p-type, in the semiconductor device. The availability of semiconductor heterostructures, homostructures, semiconductor active layers, quantum wells, multiple quantum wells, double heterostructures, superlattice layers, isolation layers, light reflecting films and multilayers, metal contact layers, passivation layers, confinement layers, cladding layers, Schottky barriers and substrates can be used to fabricate semiconductor devices and can be used to increase the function, capability, performance and application of semiconductor devices.

### EXAMPLES AND EMBODIMENTS OF THE INVENTION

MQW: A first embodiment of the present invention is a ZnO based semiconductor LED device with a structure as shown in FIG. 1. The LED device in FIG. 1 has a MQW structure comprised of alternating layers of ZnO and ZnBeO semiconductor layers with the MQW active layer region formed between confinement and cladding layers, with semiconductor layers laminated successively on a n-type SiC substrate. In one example the thickness of each of the ZnO layers in the active layer region was about 3 nm, the thickness of each of the ZnBeO layers in the active layer region was about 5 nm, each of the ZnO semiconductor active layers in the active layer region was undoped, and each of the ZnBeO semiconductor well boundary layers in the active layer region was undoped.

In other such examples, a ZnO semiconductor active layer may be doped or undoped, and may contain also one or more of the elements Si, Se, Cd and Ba; and a ZnBeO semiconductor well boundary layer may be doped or undoped. The active layers can be composed of ZnO or ZnCdOSe materials; or of ZnBeO material for which the value of the energy band gap is smaller than its boundary layers such that one or more discrete energy levels are formed in the potential well structure formed thereby.

The device structure was grown on an n-type single crystal silicon carbide substrate using by way of example, the above-described HBD process for film growth. (In another such example, the structure is contained within a semiconductor LED device that has been deposited on a single crystal zinc oxide substrate using, for example, the HBD process for film growth.)

More particularly, as discussed in greater detail below, the substrate shown in FIG. 1 is n-type doped single crystal silicon carbide (SiC). The semiconductor wafer is formed on the substrate by successive lamination of layers of semiconductor materials of the following composition and thicknesses in a reactor using the method of hybrid beam deposition (HBD) growth: a 50 nm thick, undoped ZnO buffer layer; a 250 nm, n-type ZnO layer doped with gallium (Ga); a 100 nm, n-type ZnBeO cladding and confinement layer doped with Ga; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 100 nm, p-type ZnBeO cladding and confinement layer doped with arsenic (As); and a 300 nm, p-type ZnO cap layer doped with As.

After removal from the reactor, semiconductor devices were patterned and electrical contact layers were added to the substrate and cap layers and electrical leads were attached.

The semiconductor active layer region of the MQW LED device shown in FIG. 1 is comprised of alternating layers of ZnO and ZnBeO in number sufficient to form seven quantum wells. The layer thickness values for the ZnO and ZnBeO quantum well layers were selected such that one or more quantized energy levels are formed in each quantum well.

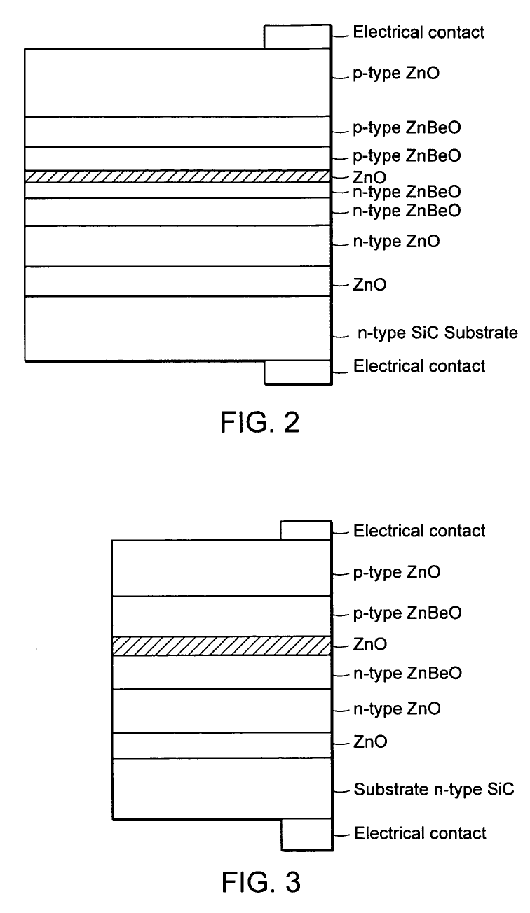

SQW: A second embodiment of the present invention is a ZnO based semiconductor p-n junction device of the type shown in FIG. 2 that has a single quantum well (SQW) structure, comprised of a ZnO semiconductor active layer that is bounded by layers of ZnBeO alloy semiconductor material to form a single quantum well with one or more discrete energy levels. In one example the thickness of the ZnO active layer was about 3 nm and undoped, the thickness of the ZnBeO confinement layers was about 20 nm, and the thickness of the cladding layer was about 80 nm. In other examples the ZnO semiconductor active layer may be p-type doped with As. The ZnO semiconductor active layer may contain also one or more of the elements Si, Se, Cd and Ba.

In one such example the active layers were composed of ZnO material. The active layers alternatively may be composed of ZnCdOSe material, of ZnBeO material for which the value of the energy band gap is sufficiently small in comparison with the energy band gaps of adjacent bounding layer that a potential well is formed and with one or more discrete energy levels formed in the potential well structure.

In a particular example, the device structure of FIG. 2 was grown on an n-type single crystal silicon carbide substrate using by way of example, the HBD process for film growth. (In another such example the structure is contained within a semiconductor p-n junction device that has been deposited on a single crystal zinc oxide substrate using, by way of example, the HBD process for film growth.) In the illustrated example, the semiconductor wafer is formed on the substrate by successive lamination of layers of materials of the following composition and thicknesses in a reactor using the method of hybrid beam deposition (HBD) growth: a 50 nm thick, undoped ZnO buffer layer; a 250 nm, n-type ZnO layer doped with Ga; a 80 nm, n-type ZnBeO cladding layer doped with Ga; a 20 nm, n-type ZnBeO confinement layer doped with Ga; a 3 nm undoped ZnO layer; a 20 nm, p-type ZnBeO confinement layer doped with As; a 80 nm, p-type ZnBeO cladding layer doped with As; and a 300 nm, p-type ZnO cap layer doped with As. The value of the energy band gap for the confinement layer is larger than that of the cladding layer.

After removal from the reactor, semiconductor p-n junction structure devices were patterned and electrical contact layers were added to the substrate and cap layers and electrical leads were attached.

For the SQW p-n junction structure device shown in FIG. 2, the semiconductor active layer region is comprised of alternating layers of ZnO and ZnBeO in number sufficient to form a single quantum well. The layer thickness values for the ZnO and ZnBeO quantum well layers were selected such that one or more quantized energy levels are formed in the quantum well.

DH: FIG. 3 shows a third embodiment of the present invention, a ZnO based semiconductor p-n junction device that has a double heterostructure (DH), comprised of a ZnO semiconductor active layer that is bounded on each side by a layer of ZnBeO alloy semiconductor material to form a heterojunction wherein the thickness of the ZnO semiconductor active layer and of the bounding layers is such that no quantized energy level can be observed in the potential well.

In one such example the ZnO semiconductor active layer is undoped. The ZnO semiconductor active layer may contain also one or more of the elements Si, Se, Cd and Ba.

In one such example the confinement layer and the cladding layer comprise one layer. In another such example the confinement layer and the cladding layer may be separate layers or layer structures. The value of energy band gap for the confinement layer may be different from that of the cladding layer.

In one such example the active layers were composed of ZnO material. In another such example the active layers may be composed of ZnCdOSe material. The active layers also can be composed of ZnBeO material for which the value of the energy band gap is sufficiently small in comparison with adjacent layers that a potential well is formed in the DH structure wherein the thickness of the ZnBeO semiconductor active layer is such that no quantized energy level may be observed in the potential well.

The device structure of FIG. 3 was grown on an n-type single crystal silicon carbide substrate using by way of example, the HBD process for film growth. (In another such example the p-n junction with DH structure may be deposited on a single crystal zinc oxide substrate using, by way of example, the HBD process for film growth.) In the illustrated example, the substrate is n-type doped single crystal silicon carbide SiC. The wafer is formed on the substrate by successive lamination of layers of materials of the following composition and thicknesses in a reactor using the method of hybrid beam deposition (HBD) growth: a 50 nm thick, undoped ZnO buffer layer; a 250 nm, n-type ZnO layer doped with Ga; a 100 nm, n-type ZnBeO cladding and confinement layer doped with Ga; a 20 nm undoped ZnO layer; a 100 nm, p-type ZnBeO cladding and confinement layer doped with As; and a 300 nm, p-type ZnO cap layer doped with As.

After removal from the reactor, devices were patterned and electrical contact layers were added to the substrate and cap layers and electrical leads were attached.

For the DH p-n junction device shown in FIG. 3, the semiconductor layer thickness values for the ZnO and ZnBeO layers were selected such that no quantized energy levels associated with the potential well were observed.

Those skilled in the art will understand that the energy band gap value of a ZnBeO alloy film can be varied from approximately 3.3 eV to approximately 10.6 eV, more or less, by adjusting independently the atomic fraction of Be from 0 to 1 in the ZnBeO alloy.

The energy band gap value of a ZnCdOSe alloy film can be varied from approximately 3.3 eV to approximately 1.75 eV, more or less, by adjusting independently the atomic fraction of Cd and the atomic fraction of Se from 0 to 1 in the ZnCdOSe alloy.

The energy band gap of the ZnBeO alloy film can be made to be approximately 10.6 eV, more or less, by growing BeO.

In accordance with these examples of the invention, ZnBeO alloys, ZnCdOSe alloys, BeO and other metal oxides and metal oxide alloys can be used, individually or in various combinations, or in various combinations with ZnO or other semiconductor materials, to form useful layers and structures, including, but not limited to, semiconductor heterostructures, semiconductor active layers, quantum wells, multiple quantum wells, double heterostructures, superlattice layers, isolation layers, light reflecting films and multilayers, metal contact layers, passivation layers, confinement layers, cladding layers, Schottky barriers and substrates. These structures can be used to fabricate semiconductor devices and can be used to increase the function, capability, performance and application of semiconductor devices.

By way of example, using these principles of the present invention, a ZnO based semiconductor LED device may be fabricated that is comprised of one or more active layer regions with the composition and thicknesses of active layers and the composition and thicknesses of bounding layers selected so that the semiconductor device can emit at one or at a multiplicity of wavelengths in the UV and visible spectral regions.

Analogously, a ZnO based semiconductor LD device may be fabricated that is comprised of one or more active layer regions with the composition and thicknesses of active layers and the composition and thicknesses of bounding layers selected so that the semiconductor device can emit at selected wavelengths in the UV and visible spectral regions.

A ZnO based semiconductor LD device may be fabricated that is comprised of one or more active layer regions with the composition and thickness of each active layer and the composition and thickness of bounding layers selected so that the semiconductor device can emit at one or at a multiplicity of wavelengths in the UV and visible spectral regions.

ZnO based semiconductor detector devices may be fabricated with layer composition and layer structures selected so that the semiconductor device can detect at one or at a multiplicity of wavelengths in the UV and visible spectral regions.

Similarly, semiconductor devices may be fabricated that are comprised of zinc oxide based, other metal oxide, and other metal oxide alloy based semiconductor layers and film structures; and in particular, semiconductor devices may be fabricated that have desirable structures comprised of layers and layered structures having selected energy band gap values and possibly containing dopant elements and one or more other elements that can emit and/or detect at one or a multiplicity of wavelengths in the UV and visible and THz spectral regions.

Those skilled in the art will appreciate that in accordance with the invention, and analogous to the example of FIG. 1, many variations of the foregoing can be implemented. For example, a layer of the semiconductor ZnBeO alloy can be epitaxially grown on a material or substrate material of composition different from, or having a layered structure different from, a single crystal silicon carbide substrate; a layer of ZnBeO alloy can be grown that is p-type or n-type doped semiconductor material; and/or a buffer layer may or may not be grown on the substrate.

Analogously, a layer of semiconductor ZnCdOSe can be epitaxially grown on a single crystal sapphire substrate, or on a material or substrate material of composition different from a single crystal sapphire substrate; and a layer of ZnCdOSe alloy can be grown that is undoped, or p-type or n-type doped semiconductor material.

A layer of semiconductor BeO material can be epitaxially grown on a material or substrate material of composition different from a single crystal sapphire substrate; and a layer of BeO material can be grown that is undoped, p-type or n-type doped semiconductor material.

Moreover, n-type ZnBeO semiconductor alloy material can be prepared wherein the n-type dopant is an element, or more than one element, selected from the group consisting of boron, aluminum, gallium, indium, thallium, fluorine, chlorine, bromine and iodine

In addition, p-type ZnBeO semiconductor alloy material can be prepared wherein the p-type dopant is an element, or more than one element, selected from the group 1, 11, 5 and 15 elements, or wherein the p-type dopant is selected from the group consisting of arsenic, phosphorus, antimony and nitrogen, or more particularly, wherein the p-type dopant is arsenic.

Still further, n-type ZnCdOSe semiconductor alloy material can be prepared wherein the n-type dopant is an element, or more than one element, selected from the group consisting of boron, aluminum, gallium, indium, thallium, fluorine, chlorine, bromine and iodine.

In addition, p-type ZnCdOSe semiconductor alloy material can be prepared wherein the p-type dopant is an element, or more than one element, selected from the group 1, 11, 5 and 15 elements, or wherein the p-type dopant is selected from the group consisting of arsenic, phosphorus, antimony and nitrogen, or more particularly, wherein the p-type dopant is arsenic.

ZnBeO semiconductor material can be grown with an atomic fraction of Mg incorporated into the ZnBeO material for applications to form lattice matched layers wherein the ZnBeO film can be either undoped, p-type doped, or n-type doped semiconductor material; and ZnCdOSe semiconductor materials can be grown with an atomic fraction of Be incorporated into the ZnCdOSe material for applications to form lattice matched layers wherein the ZnCdOSe film can be either undoped, p-type doped, or n-type doped semiconductor material.

It will also be appreciated that n-type BeO semiconductor material can be prepared wherein the n-type dopant is an element, or more than one element, selected from the group consisting of boron, aluminum, gallium, indium, thallium, fluorine, chlorine, bromine and iodine; and p-type BeO semiconductor material can be prepared wherein the p-type dopant is an element, or more than one element, selected from the group 1, 11, 5 and 15 elements; the p-type BeO semiconductor material can be prepared wherein the p-type dopant is selected from the group consisting of arsenic, phosphorus, antimony and nitrogen; or more particularly, wherein the p-type dopant is arsenic.

Still further, n-type ZnO semiconductor material can be prepared wherein the n-type dopant is an element, or more than one element, selected from the group consisting of boron, aluminum, gallium, indium, thallium, fluorine, chlorine, bromine and iodine; and p-type ZnO semiconductor material can be prepared wherein the p-type dopant is an element, or more than one element, selected from the group 1, 11, 5 and 15 elements; the p-type ZnO semiconductor material can be prepared wherein the p-type dopant is selected from the group consisting of arsenic, phosphorus, antimony and nitrogen; or more particularly, wherein the p-type dopant is arsenic.

A semiconductor active layer may contain also one or more of the elements from the list of, but not limited to, Si, Se, Cd and Ba.

Still further, a semiconductor structure can be grown using layers of the type(s) listed above that include, but are not limited to, structures such as semiconductor heterostructures, semiconductor active layers, quantum wells, multiple quantum wells, double heterostructures, superlattice layers, isolation layers, light reflecting films and multilayers, metal contact layers, passivation layers, confinement layers, cladding layers, Schottky barriers and substrates.

A semiconductor device may be grown that is comprised of more than one type of active layer region selected from one or more of the list comprised of zinc oxide based and other metal oxide and metal oxide alloys with selected energy band gap values and possibly containing dopant elements and one or more other elements so the semiconductor device can emit, or detect, at one or a multiplicity of wavelengths in the UV and visible spectral regions.

These structures can be used to fabricate semiconductor devices and can be used to increase the function, capability, performance and application of semiconductor devices.

The present invention and its advantages will be further understood through consideration of the following additional examples and practices.

### FURTHER EXAMPLES OF PRACTICES AND EMBODIMENTS OF THE INVENTION

In one practice of the invention, a polished n-type doped silicon carbide wafer cut from a bulk crystal was used as the substrate. The wafer was placed in a hybrid beam deposition reactor, and heated to approximately 750° C. The pressure was reduced to approximately 1×10⁻⁵ torr and the substrate cleaned with an RF oxygen plasma for 30 minutes. The temperature was then lowered to 550° C., and the following laminated layers were grown in succession on the substrate: a 50 nm thick, undoped ZnO buffer layer; a 250 nm, n-type ZnO layer doped with gallium (Ga); a 100 nm, n-type ZnBeO cladding and confinement layer doped with Ga; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 5 nm undoped ZnBeO layer; a 3 nm undoped ZnO layer; a 100 nm, p-type ZnBeO cladding and confinement layer doped with arsenic (As); and a 300 nm, p-type ZnO cap layer doped with As.

During growth of the n-type ZnO layers a thermally controlled Knudsen cell containing Ga was heated to produce a beam of Ga vapor that impinged on the substrate simultaneous with the beams used to grow ZnO. During growth of the p-type ZnO layers a thermally controlled Knudsen cell containing As was heated to produce a beam of As vapor that impinged on the substrate simultaneous with the beams used to grow ZnO.

During growth of the ZnBeO alloy layers a thermally controlled Knudsen cell containing Be was heated to produce a beam of Be vapor that impinged on the substrate simultaneous with the beams used to grow ZnO.

During growth of the n-type ZnBeO layers a thermally controlled Knudsen cell containing Ga was heated to produce a beam of Ga vapor that impinged on the substrate simultaneous with the beams used to grow ZnBeO. During growth of the p-type ZnBeO layers a thermally controlled Knudsen cell containing As was heated to produce a beam of As vapor that impinged on the substrate simultaneous with the beams used to grow ZnBeO.

The temperature was lowered to room temperature and the wafer was removed from the chamber.

A more detailed description of hybrid beam deposition (HBD) processes for depositing a zinc oxide layer, an n-type zinc oxide layer, and a p-type zinc oxide layer, and in particular a p-type zinc oxide layer doped with arsenic, is set forth in one or more of commonly owned U.S. Pat. Nos. 6,475,825 and 6,610,141, and Patent Applications U.S. 60/406,500, PCT/US03/27143 and U.S. Ser. No. 10/525,611, each of which is hereby incorporated by reference as if set forth in its entirety herein.

The wafer was patterned and cut to form individual device units. Electrical leads were attached to the n-type silicon carbide substrate and to the cap layer. FIG. 1 shows a layer schematic of the MQW LED semiconductor device that was fabricated using these techniques.

I-V characteristics were then obtained at room temperature using a semiconductor parameter analyzer.

In a second practice of the invention, a polished n-type doped silicon carbide wafer cut from a bulk crystal was used as the substrate. The wafer was placed in a hybrid beam deposition reactor, and heated to approximately 750° C. The pressure was reduced to approximately 1×10⁻⁵ torr and the substrate cleaned with an RF oxygen plasma for 30 minutes. The temperature was then lowered to 550° C., and the following laminated layers were grown in succession on the substrate: a 50 nm thick, undoped ZnO buffer layer; a 250 nm, n-type ZnO layer doped with Ga; a 80 nm, n-type ZnBeO cladding layer doped with Ga; a 20 nm, n-type ZnBeO confinement layer doped with Ga; a 3 nm undoped ZnO layer; a 20 nm, p-type ZnBeO confinement layer doped with As; a 80 nm, p-type ZnBeO cladding layer doped with As; and a 300 nm, p-type ZnO cap layer doped with As. The value of the energy band gap for the confinement layer is larger than that of the cladding layer.

Growth of ZnO layers, n-type ZnO layers, p-type ZnO layers, n-type ZnBeO layers, and p-type ZnBeO layers were made in the same method as described for the first embodiment.

The temperature was lowered to room temperature and the wafer was removed from the chamber. The wafer was patterned and cut to form individual device units. Electrical leads were attached to the n-type silicon carbide substrate and to the cap layer. FIG. 2 shows a layer schematic of the SQW LED semiconductor device that was fabricated.

I-V characteristics were then obtained at room temperature using a semiconductor parameter analyzer.

In a third practice of the invention, a polished n-type doped silicon carbide wafer cut from a bulk crystal was used as the substrate. The wafer was placed in a hybrid beam deposition reactor, and heated to approximately 750° C. The pressure was reduced to approximately 1×10⁻⁵ torr and the substrate cleaned with an RF oxygen plasma for 30 minutes. The temperature was then lowered to 550° C., and the following laminated layers were grown in succession on the substrate: a 50 nm thick, undoped ZnO buffer layer; a 250 nm, n-type ZnO layer doped with Ga; a 100 nm, n-type ZnBeO cladding and confinement layer doped with Ga; a 20 nm undoped ZnO layer; a 100 nm, p-type ZnBeO cladding and confinement layer doped with As; and a 300 nm, p-type ZnO cap layer doped with As.

Growth of ZnO layers, n-type ZnO layers, p-type ZnO layers, n-type ZnBeO layers, and p-type ZnBeO layers were made in the same method as described for the first embodiment.

The temperature was lowered to room temperature and the wafer was removed from the chamber. The wafer was patterned and cut to form individual device units. Electrical leads were attached to the n-type silicon carbide substrate and to the cap layer. FIG. 2 shows a layer schematic of the p-n junction semiconductor device with DH structure that was fabricated.

I-V characteristics were then obtained at room temperature using a semiconductor parameter analyzer.

For comparison purposes, I-V characteristics were obtained at room temperature using a semiconductor parameter analyzer for a several ZnO based semiconductor devices, including but not limited to an MQW LED device, a p-n junction structure device having a DH structure, and a p-n junction structure device having a homostructure. These semiconductor devices were fabricated from wafers grown by the HBD process with n-type SiC as the substrate.

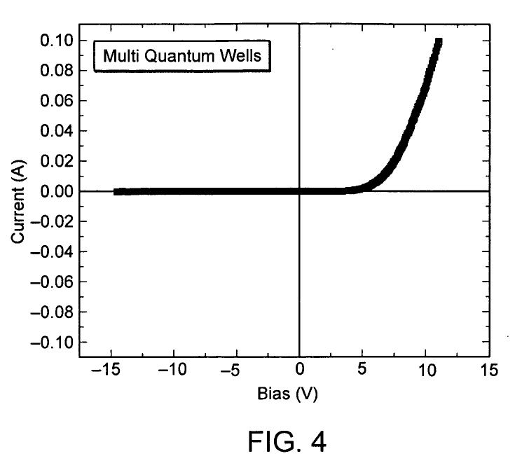

FIG. 4 shows room temperature I-V characteristics for a MQW ZnO based semiconductor LED device in accordance with the invention, with layer structure as illustrated in FIG. 1.

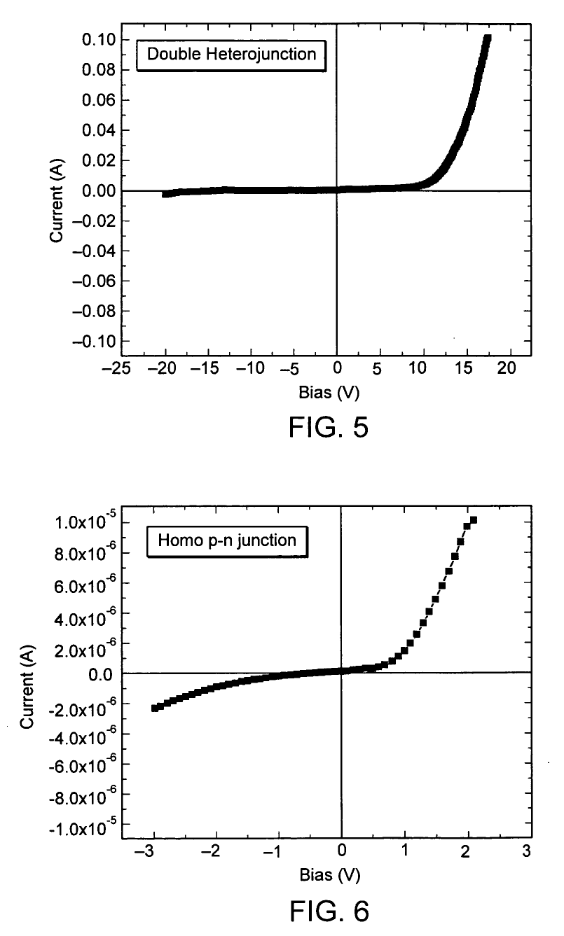

FIG. 5 shows room temperature I-V characteristics for a double heterostructure (DH) ZnO based semiconductor p-n junction with structure as shown in FIG. 3.

FIG. 6 shows room temperature I-V characteristics for a homostructure ZnO based semiconductor p-n junction formed on an n-type SiC substrate.

Comparison of I-V data showed that the I-V characteristics of the DH structure ZnO based semiconductor p-n junction shown in FIG. 5 are more similar to the I-V characteristics of an ideal p-n junction than are the I-V characteristics of the homostructure ZnO based semiconductor p-n junction shown in FIG. 6; and that the I-V characteristics of the MQW ZnO based semiconductor p-n junction shown in FIG. 4 are more similar to the I-V characteristics of an ideal p-n junction than are the I-V characteristics of the DH structure ZnO based semiconductor p-n junction shown in FIG. 5.

For excitation voltages above a threshold voltage, the MQW LED of FIG. 1 emitted light in the UV/blue region of the spectrum that could be easily observed by human eye that appeared as a whitish-blue color and emitted light could be spectrographically recorded.

As noted above, the present invention relates to zinc oxide based semiconductor devices and other metal oxide based semiconductor devices and metal oxide alloy semiconductor devices comprised of alloy semiconductor materials that can be fabricated with a range of desirable energy band gap values, and which can be used to fabricate semiconductor structures and devices, and to improve the function and performance of semiconductor devices. Although embodiments of the invention are described herein with respect to a ZnO based semiconductor active layer and ZnBeO based semiconductor based alloys to form an LED having an MQW structure active layer region, or an LED having an SQW structure active layer region, or a p-n junction device having a DH structure active layer region, it will be understood that the invention may also be practiced in connection with forming such respective structures by use of layers and structures comprised of other ZnO based materials, other ZnO alloy based materials, other metal oxide based semiconductor materials, other metal oxide alloy based materials, BeO based materials, BeO based alloy materials, ZnBeO based alloy materials and to other types of ZnO alloys, such as, for example, ZnCdOSe alloys and ZnCdOSe alloy based materials.

In addition, while embodiments of the invention are described with respect to a ZnO based semiconductor active layer and ZnBeO based semiconductor based alloys to form an LED having an MQW structure active layer region, it will be understood that the invention also may be practiced with respect to forming an LD having an MQW structure by use of layers and structures comprised of ZnO and ZnBeO based materials.

Although one embodiment of the present invention is described with respect to a ZnO based semiconductor active layer and ZnBeO based semiconductor based alloys to form an LED having a MQW structure active layer region, it will be understood that the present invention may be practiced with respect to forming an LD having an MQW structure by use of layers and structures comprised of other ZnO based materials, other ZnO alloy based materials, other metal oxide based semiconductor materials, other metal oxide alloy based materials, other BeO based materials, other BeO based alloy materials, other ZnBeO based alloy materials, other types of ZnO alloys, such as, for example, ZnCdOSe alloys and ZnCdOSe alloy based materials, and other substrate materials such as, for example, ZnO, sapphire, gallium nitride, and layered structures comprised of two or more layers of materials, such as, for example, a layer of gallium nitride on sapphire or a layer of gallium nitride on silicon.

It is also noted that in accordance with the invention, semiconductor devices can be fabricated using ZnBeO semiconductor material that can be grown with the atomic fraction of Be to be any desirable value between 0 and 1.

Semiconductor devices also can be fabricated in accordance with the invention using ZnBeO, ZnCdOSe or BeO semiconductor materials that can be grown with, in the case of ZnBeO or ZnCdOSe, respectively, the atomic fraction of Be or Cd and Se to be any desirable value between 0 and 1; wherein the ZnBeO or ZnCdOSe semiconductor material is undoped, p-type or n-type doped, grown on materials or substrates including, but not limited to, ZnO, GaN, and SiC, and is of sufficient crystal quality to be used to fabricate semiconductor structures and devices.

Semiconductor devices also can be fabricated in accordance with the invention using ZnBeO semiconductor alloys, ZnCdOSe semiconductor alloys, and BeO semiconductor materials, including undoped, p-type doped, and n-type doped semiconductor materials, can be grown and used, separately or in various combinations, or in various combinations with ZnO or other semiconductor materials, to form layers and structures including, but not limited to, semiconductor heterostructures, homostructures, semiconductor active layers, quantum wells, multiple quantum wells, double heterostructures, superlattice layers, isolation layers, light reflecting films and multilayers, metal contact layers, passivation layers, confinement layers, cladding layers, Schottky barriers and substrates; can be used to fabricate semiconductor devices; and can be used to increase the function, capability, performance and application of semiconductor devices.

In accordance with the present invention, semiconductor devices comprised of structures formed with semiconductor materials including, but not limited to, metal oxides, metal oxide alloys, ZnO, ZnO alloys, ZnBeO, ZnBeO alloys, ZnCdOSe, ZnCeOSe alloys, BeO and BeO alloys, including undoped, p-type doped, and n-type doped semiconductor materials, can be used for fabricating photonic and electronic semiconductor devices for use in photonic and electronic applications.

Uses for such devices include, but are not limited to, devices such as LEDs, LDs, FETs, PN junctions, PIN junctions, Schottky barrier diodes, UV and visible range transmitters and detectors, transistors and transparent transistors which can be employed in applications such as light emitting displays, other transistors and transparent transistors, backlighting for displays, high frequency radar, biomedical imaging, chemical compound identification, molecular identification and structure, gas sensors, imaging systems, and fundamental studies of atoms, molecules, gases, vapors and solids.

Also in accordance with the invention, such semiconductor devices, structures and materials can be employed to fabricate LEDs and LDs that have one or a multiplicity of emission wavelengths in the spectral range from approximately 117 nm to approximately 710 nm; and semiconductor devices, structures and materials can be employed to fabricate sensors and detectors that have one or a multiplicity of detection wavelengths in the spectral range from approximately 117 nm to approximately 710 nm.

Further in accordance with the invention, semiconductor devices and structures can be comprised of ZnBeO and BeO semiconductor materials grown with an atomic fraction of Mg incorporated therein during growth, for use in applications to form lattice matched layers, wherein the ZnBeO or BeO materials containing Mg may be undoped, p-type or n-type doped semiconductor materials.

Semiconductor devices and structures in accordance with the invention also can be comprised of ZnCeOSe alloy semiconductor materials grown with an atomic fraction of Be incorporated therein during growth, for use in applications to form lattice matched layers, wherein the ZnCdOSe materials containing Be may be undoped, p-type or n-type doped semiconductor materials.

Also in accordance with the invention, semiconductor devices and structures can be formed on substrates comprised of a single layer crystal material; on a substrate comprised of one or more layers of a material grown on another material; on substrates comprised of a single layer crystal materials selected from a list including but not limited to silicon carbide, zinc oxide, sapphire, and gallium nitride; and/or on substrates having a layered structure comprised of two or more layers of material selected from a list including but not limited to gallium nitride deposited on sapphire and gallium nitride deposited on silicon.

The materials, layers and structures described herein can be incorporated into semiconductor devices for improvement in performance, function and capability and speed of such devices.

Those skilled in the art will appreciate that various modifications, additions and other changes can be made in the devices, materials, layers, structures and implementations described herein, and that various modifications are possible within the spirit and scope of the invention as claimed. The terms and expressions used herein are terms of description and not of limitation, and there is no intention in the use of such terms and expressions to exclude equivalents of the features shown and described, or portions thereof. In addition, any one or more features and aspects of the invention can be combined with one or more other features of the invention, without departing from the spirit and scope of the invention, which is limited solely by the appended claims.

1. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one oxide semiconductor layer between said n-type semiconductor region and said p-type semiconductor region,
wherein said active layer region contains at least one multiple quantum well (MQW) structure.

2. An oxide semiconductor device comprising:
a substrate,
an n-type semiconductor region comprising at least one oxide semiconductor layer,
a p-type semiconductor region comprising at least one semiconductor layer, and
an active layer region comprising at least one oxide semiconductor layer between said n-type semiconductor region and said p-type semiconductor region,
wherein said active layer region contains at least one single quantum well (SQW) structure.

3. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one oxide semiconductor layer between said n-type semiconductor region and said p-type semiconductor region,
wherein said active layer region contains at least one double heterostructure (DH).

4. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one semiconductor layer between said n-type semiconductor region and said p-type semiconductor region,
wherein said active layer region contains at least one superlattice (SL) structure.

5. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one oxide semiconductor layer between said n-type semiconductor region and said p-type semiconductor region,
wherein said active layer region contains at least one structure comprising a set of alternating quantum well layers and barrier layers that have larger energy band gap values than the quantum well layers, such that a multiplicity of quantum wells are formed, and
wherein at least one discrete energy level is formed in each of the quantum wells.

6. An oxide semiconductor device comprising:
a substrate,
an n-type semiconductor region comprising at least one semiconductor layer,
a p-type semiconductor region comprising at least one oxide semiconductor layer, and
an active layer region comprising at least one oxide semiconductor layer between said n-type semiconductor region and said p-type semiconductor region,
wherein said active layer region contains at least one structure comprising a quantum well layer with a thickness bounded by barrier layers that have energy gap values larger than the quantum well layer and thereby forming a quantum well, with the thickness of the quantum well layer and the thicknesses of the boundary layers sufficient to form at least one discrete energy levels in the quantum well.

7. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one oxide semiconductor layer between said n-type semiconductor region and said p-type semiconductor region,
wherein the active layer region contains at least one structure comprising layers laminated successively to form at least two interfaces, with a composition of materials on each side of a middle layer different from that of the middle layer, with energy band gap values of the materials on each side of the middle layer different from that of the middle layer, and with the thickness of the middle layer and the thickness of each boundary layer selected such that the structure does not evidence the presence of at least one quantized energy level in the structure.

8. An oxide semiconductor device comprising:
a substrate,
an n-type semiconductor region comprising at least one oxide semiconductor layer,
a p-type semiconductor region comprising at least one oxide semiconductor layer, and
an active layer region comprising at least one oxide semiconductor layer between said n-type semiconductor region and said p-type semiconductor region,
wherein the active layer region contains at least one structure comprised of layers of semiconductor material having different composition, and
wherein each layer is sufficiently thin that it can strain if necessary to form an epitaxial layer with adjacent layers.

9. The device of claim 1, comprising at least one oxide material selected from a list comprising semiconductor oxide, semiconductor oxide alloy, semiconductor metal oxide, semiconductor metal oxide alloy, semiconductor ZnO, semiconductor zinc oxide alloy, semiconductor ZnO based alloy, semiconductor BeO, semiconductor BeO alloy, semiconductor ZnBeO, semiconductor ZnBeO alloy, semiconductor ZnCdSeO, semiconductor ZnCdSeO alloy, semiconductor Zn₁₋ₓBeₓO with x varying between 0 and 1 as required, semiconductor Zn_{1-y}Cd_{y}O_{1-z}Se_{z} with y varying between 0 and 1 as required and with z varying between 0 and 1 independently as required.

10. The device of claim 1, wherein said n-type semiconductor region is comprised of at least one superlattice structure comprised of layers of semiconductor material having different composition and wherein each layer is sufficiently thin that it can strain if necessary to form an epitaxial layer with adjacent layers.

11. The device of claim 1, wherein said p-type semiconductor region is comprised of at least one superlattice structure comprised of layers of semiconductor material having different composition, and wherein each layer is sufficiently thin that it can strain if necessary to form an epitaxial layer with adjacent layers.

12. The device of claim 1, wherein said n-type semiconductor region comprises at least one of a superlattice structure, a confinement layer, a cladding layer, an optical waveguide layer, a light reflection layer, an absorption layer, a transmission layer, an isolation layer, a metal contact layer, a passivation layer, and a cap layer.

13. The device of claim 1, wherein said p-type semiconductor region contains at least one of a superlattice structure, a confinement layer, a cladding layer, an optical waveguide layer, a light reflection layer, an absorption layer, a transmission layer, an isolation layer, a metal contact layer, a passivation layer, and a cap layer.

14. The device of claim 1, wherein the semiconductor device is of a type selected from the list comprising: a light emitting diode, laser diode, transistor, transparent transistor, field effect transistor, p-n junction, PIN junction, Schottky barrier diode, ultraviolet spectral range detector, visible spectral range detector, ultraviolet spectral range transmitter, visible spectral range transmitter, light emitting display, backlight for a display, high frequency transmitter, high frequency detector, high frequency transmitter in the gigahertz range, high frequency detector in the gigahertz range, high frequency transmitter in the terahertz range, high frequency detector in the terahertz range, imaging display, device for chemical compound identification, gas sensor, liquid sensor, atom sensor, molecule sensor, vapor sensor and solid sensor.

15. The device of claim 1, wherein the substrate is undoped, p-type doped, or n-type doped.

16. The device of claim 1, wherein the substrate is selected from the list comprising silicon carbide, zinc oxide, sapphire, and gallium nitride.

17. The device of claim 1, wherein the substrate is a layered structure comprising at least two layers of material.

18. The device of claim 1, wherein the substrate is a layered structure comprising at least two layers of material selected from the list that includes, but is not limited to, gallium nitride deposited on sapphire, and gallium nitride deposited on silicon.

19. The device of claim 1, wherein the substrate is undoped.

20. The device of claim 1, wherein the substrate is p-type doped.

21. The device of claim 1, wherein the substrate is n-type doped.

22. The device of claim 1, wherein at least one of the layers in an active layer region is undoped.

23. The device of claim 1, wherein at least one of the layers in an active layer region is p-type doped with at least one element selected from the group consisting of 1, 11, 5 and 15 elements.

24. The device of claim 1, wherein at least one of the layers in an active layer region is p-type doped with at least one element selected from the list consisting of arsenic, phosphorus, antimony and nitrogen.

25. The device of claim 1, wherein at least one of the layers in an active layer region is p-type doped with arsenic.

26. The device of claim 1, wherein at least one of the layers in an active layer region is n-type doped with at least one element selected from the group consisting of boron, aluminum, gallium, indium, thallium, fluorine, chlorine, bromine and iodine.

27. The device of claim 1, wherein at least one of the layers in an active layer region is n-type doped with gallium.

28. The device of claim 1, wherein at least one of the layers in an active layer region is undoped, p-type doped, or n-type doped semiconductor material that contains an atomic fraction of Mg for the purpose of forming lattice matching layers in semiconductor structures and devices.

29. The device of claim 1, wherein at least one of the layers in an active layer region is undoped, p-type doped, or n-type doped semiconductor material that contains an atomic fraction of Be for the purpose of forming lattice matching layers in semiconductor structures and devices.

30. The device of claim 1, wherein at least one of the layers in a semiconductor structure adjoining a semiconductor active layer region and such adjoining semiconductor structure and layers having energy band gap values larger than the energy band gap value of the semiconductor active layer region is undoped.

31. The device of claim 1, wherein at least one of the layers in a semiconductor structure adjoining a semiconductor active layer region and such adjoining semiconductor structure and layers having energy band gap values larger than the energy band gap value of the semiconductor active layer region is p-type doped with at least one element selected from the group consisting of 1, 11, 5 and 15 elements.

32. The device of claim 1, wherein at least one of the layers in a semiconductor structure adjoining a semiconductor active layer region and such adjoining semiconductor structure and layers having energy band gap values larger than the energy band gap value of the semiconductor active layer region is p-type doped with at least one element selected from the list consisting of arsenic, phosphorus, antimony and nitrogen.

33. The device of claim 1, wherein at least one of the layers in a semiconductor structure adjoining a semiconductor active layer region and such adjoining semiconductor structure and layers having energy band gap values larger than the energy band gap value of the semiconductor active layer region is p-type doped with arsenic.

34. The device of claim 1, wherein at least one of the layers in a semiconductor structure adjoining a semiconductor active layer region and such adjoining semiconductor structure and layers having energy band gap values larger than the energy band gap value of the semiconductor active layer region is n-type doped with at least one element selected from the group consisting of boron, aluminum, gallium, indium, thallium, fluorine, chlorine, bromine and iodine.

35. The device of claim 1, wherein at least one semiconductor layer adjoining a semiconductor active layer and having energy band gap values larger than the energy band gap value of the semiconductor active layer is undoped, p-type doped, or n-type doped semiconductor material that contains an atomic fraction of Mg for the purpose of forming lattice matching layers in semiconductor structures and devices.

36. The device of claim 1, wherein at least one semiconductor layer adjoining a semiconductor active layer and having energy band gap values larger than the energy band gap value of the semiconductor active layer is undoped, p-type doped, or n-type doped semiconductor material that contains an atomic fraction of Be for the purpose of forming lattice matching layers in semiconductor structures and devices.

37. The device of claim 1, wherein a buffer layer is formed on the substrate prior to deposition of additional layers.

38. The device of claim 1, wherein no buffer layer is formed on the substrate prior to deposition of additional layers.

39. The device of claim 1, wherein the semiconductor device formed on a substrate is an LED with a MQW structure, and the thickness of the active layer is less than about 10 nm and greater than about 0.5 nm, and the thickness of the bounding layers with higher energy band gap values is less than about 500 nm and greater than about 1 nm.

40. The device of claim 1, wherein the semiconductor device formed on a substrate is an LED with a MQW structure, and the thickness of the active layer is about 2 nm, and the thickness of the bounding layers with higher energy band gap values is about 200 nm.

41. The device of claim 2, wherein the semiconductor device formed on a substrate is an LED with a SQW structure, and the thickness of the active layer is less than about 10 nm and greater than about 0.5 nm, and the thickness of the bounding layers with higher energy band gap values is less than about 500 nm and greater than about 1 nm.

42. The device of claim 2, wherein the semiconductor device formed on a substrate is an LED with a SQW structure, and the thickness of the active layer is about 2 nm, and the thickness of the bounding layers with higher energy band gap values is about 200 nm.

43. The device of claim 1, wherein the semiconductor device formed on a substrate is an LD with a MQW structure, and the thickness of the active layer is less than about 10 nm and greater than about 0.5 nm, and the thickness of the bounding layers with higher energy band gap values is less than about 500 nm and greater than about 1 nm.

44. The device of claim 1, wherein the semiconductor device formed on a substrate is an LD with a MQW structure, and the thickness of the active layer is about 2 nm, and the thickness of the bounding layers with higher energy band gap values is about 200 nm.

45. The device of claim 2, wherein the semiconductor device formed on a substrate is an LD with a SQW structure, and the thickness of the active layer is less than about 10 nm and greater than about 0.5 nm, and the thickness of the bounding layers with higher energy band gap values is less than about 500 nm and greater than about 1 nm.

46. The device of claim 2, wherein the semiconductor device formed on a substrate is an LD with a SQW structure, and the thickness of the active layer is about 2 nm, and the thickness of the bounding layers with higher energy band gap values is about 200 nm.

47. The device of claim 1, wherein the semiconductor device formed on a substrate is an LED with a MQW structure that has at least one emission wavelength in the spectral range from approximately 117 nm to approximately 710 nm.

48. The device of claim 2, wherein the semiconductor device formed on a substrate is an LED with a SQW structure that has at least one emission wavelength in the spectral range from approximately 117 nm to approximately 710 nm.

49. The device of claim 2, wherein the semiconductor device formed on a substrate is an LD with a MQW structure that has at least one emission wavelength in the spectral range from approximately 117 nm to approximately 710 nm.

50. The device of claim 2, wherein the semiconductor device formed on a substrate is an LD with a SQW structure that has at least one emission wavelength in the spectral range from approximately 117 nm to approximately 710 nm.

51. The device of claim 1, wherein the semiconductor device formed on a substrate can detect at least one emission wavelength in the spectral range from approximately 117 nm to approximately 710 nm.

52. The device of claim 1, wherein a superlattice structure is used to form at least one of a semiconductor passivation layer, confinement layer, cladding layer, optical reflection layer, optical reflecting film, optical absorption layer, optical transmission layer, isolation layer, or metal contact layer.

53. The device of claim 1, wherein the semiconductor oxide material is selected from the list comprising semiconductor metal oxides, metal oxide alloys, ZnO, ZnO based alloys, BeO, BeO based alloys, ZnBeO, ZnBeO based alloys, ZnCdSeO, and ZnCdSeO based alloys, with each material either undoped, n-type doped, or p-type doped.
